(19) United States
(12) Patent Application Publication
(10) Pub. No.: US 2011/0025396 A1
(43) Pub. Date: Feb. 3, 2011

(54) Digital Attenuator Circuits and Methods for Use thereof

(75) Inventor: Jan-Michael Stevenson, Frisco, TX (US)

Correspondence Address: FULBRIGHT & JAWORSKI L.L.P, 2200 ROSS AVENUE, SUITE 2800, DALLAS, TX, 75201-2784, US

(73) Assignee: Microtune (Texas), L.P., Plano, TX (US)

(21) Appl. No.: 12/904,048

(22) Filed: Oct. 13, 2010

Related U.S. Application Data
(63) Continuation-in-part of application No. 12/352,430, filed on Jan. 12, 2009.
Application No. 12/352,430 is a continuation of application No. 11/442,643, filed on May 26, 2006, now Pat. No. 7,477,085.

(51) Int. Cl. H03L 5/00

(52) U.S. Cl. 327/308

(57) ABSTRACT

An attenuator system includes a first adjustable impedance component on a first current path between a input component and a output component, and a second adjustable impedance component between the first current path and ground, wherein each of the first and second adjustable impedance components include a plurality of selectable, discrete legs, each leg having an impedance.

### CROSS-REFERENCE TO RELATED APPLICATIONS

This application is a continuation-in-part of U.S. patent application Ser. No. 12/352,430 filed Jan. 12, 2009 and entitled, “AGC METHOD USING DIGITAL GAIN CONTROL,” which is a continuation of U.S. patent application Ser. No. 11/442,643 filed May 26, 2006 and entitled “DIGITAL ATTENUATOR CIRCUITS AND METHODS FOR USE THEREOF,” the disclosures of which are hereby incorporated herein by reference.

The present application is also related to co-pending and commonly-assigned U.S. patent application Ser. No. 11/441,816 filed May 26, 2006, entitled, “AGC SYSTEM AND METHOD FOR BROADBAND TUNERS,” the disclosure of which is hereby incorporated herein by reference.

### TECHNICAL FIELD

The present description relates, in general, to attenuator circuits, and more specifically, to digitally-controllable attenuator circuits.

### BACKGROUND OF THE INVENTION

In prior art Radio Frequency (RF) tuners, Automatic Gain Control (AGC) is often performed at the beginning of the RF signal path before the signal is fed to distortion-causing circuitry, such as amplifiers. For instance, tuners typically maintain an output signal power level at or below a certain reference value. The reference value is usually based on an assumption that the signal power level at any point in the signal path is unlikely to drive a component “to the rails” if the output signal is at or below the reference value. Attenuation is performed on the signal input when it is determined that the output signal power level is above the reference value.

In one prior art application, analog AGC is performed inside the first amplifier itself. However, this approach is prone to distortion, since the AGC is performed inside the amplifier. Another approach is to use a pin-diode attenuator in the signal path before the distortion-causing circuitry. However, pin-diode attenuators typically cannot be built on a semiconductor chip, such that in tuner-on-chip applications, the attenuation is performed off-chip.

### BRIEF SUMMARY OF THE INVENTION

Various embodiments of the present invention are directed to systems and methods for providing digitally-controllable attenuation. In one example, an attenuator circuit includes a voltage-divider arrangement with two adjustable impedance components, the second of which is shunted to ground. The attenuation is a function of the relative values of the adjustable impedance components.

In this example, each of the adjustable impedance components includes a plurality of selectable, discrete elements that each have some amount of impedance. In each adjustable impedance component, selecting one or more of the elements determines the impedance of the component. Each discrete element can be switched on or off using, e.g., a transistor that is controlled by digital control lines. Thus, digital signals from the control lines can provide a range of discrete impedance values for each impedance component. Accordingly, the attenuation of the circuit is controllable digitally.

An example method using the arrangement described above includes receiving an RF signal and adjusting the impedances of the impedance components (and, therefore, the attenuation) based upon the signal level. The adjusting is performed, e.g., by switching one or more of the selectable elements in each of the impedance components using digital control lines. The values of each of the impedance components may be constrained by one or more requirements, including, e.g., input/output impedance values, linearity of operation, and relationships between changes in attenuation versus changes in noise and/or distortion.

An advantage of one or more embodiments is that the attenuator circuit can be implemented in a chip along with various other components of a tuner. In fact, one or more of such attenuator circuits can be placed along the RF signal path, including before the first amplifier. In such manner, attenuation can be performed on large input signals so that the actual signal level going into the first amplifier is at or below a “take over point,” or other reference level.

Other example embodiments include systems and methods for providing gain control in RF devices using an attenuator circuit. In one example, a series impedance component and a shunt impedance component both include binary impedance arrays. Each of the impedance components includes a plurality of selectable legs. As the attenuator circuit steps through its dynamic range it switches a leg in one component at a time so as to reduce or eliminate large, instantaneous changes in output impedance. Also, the legs can be selected using one or more patterns designed to provide an approximately linear gain slope over the dynamic range.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 is an illustration of an exemplary system adapted according to one embodiment of the invention;

FIG. 2 is an illustration of an exemplary system adapted according to one embodiment of the invention;

FIG. 3 is an illustration of an exemplary method adapted according to one embodiment for providing AGC in a circuit, such as the system of FIG. 1 or the system of FIG. 2;

FIG. 4 is an illustration of an exemplary system adapted according to one embodiment of the invention;

FIG. 5 is an illustration of an exemplary attenuator circuit, adapted according to one embodiment of the invention;

FIGS. 6A and 6B are an illustration of an exemplary method adapted according to one embodiment of the invention;

FIG. 7 shows a graph, which plots gain (in dB) against attenuation codes; and

FIG. 8 is an illustration of an exemplary method adapted according to one embodiment of the invention.

### DETAILED DESCRIPTION OF THE INVENTION

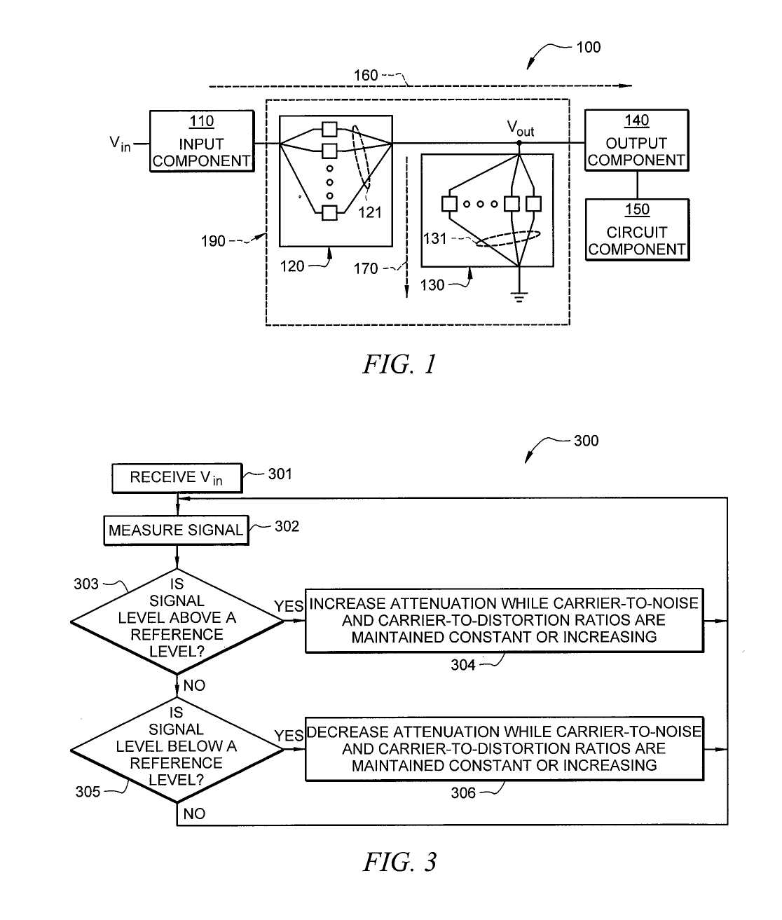

FIG. 1 is an illustration of exemplary system 100 adapted according to one embodiment of the invention. System 100 includes input component 110 receiving an input signal that has a voltage Vᵢₙ, first adjustable impedance component 120, and second adjustable impedance component 130, which is shunted to ground. Output voltage Vₒᵤₜ, at output component 140 (e.g., wire, contact, or the like), is fed to the input of circuit component 150 (e.g., amplifier, mixer, filter, or the like). First adjustable impedance component 120 may be referred to herein as a “series” component because it is in series in first current path 160 between input component 110 and output component 140. Likewise, second adjustable impedance component 130 may be referred to herein as a “shunt” component because it is shunted. Second adjustable impedance component 130 creates second current path 170.

Each of first and second adjustable impedance components 120 and 130 includes a plurality of selectable, discrete legs 121 and 131, respectively, that each have some amount of impedance. Attenuator circuit 190 can be used for Automatic Gain Control (AGC) to provide Vₒᵤₜ at an approximately constant signal level (i.e., 3 dB deviation or less from a reference value) by controlling the impedances of components 120 and 130, as explained further below.

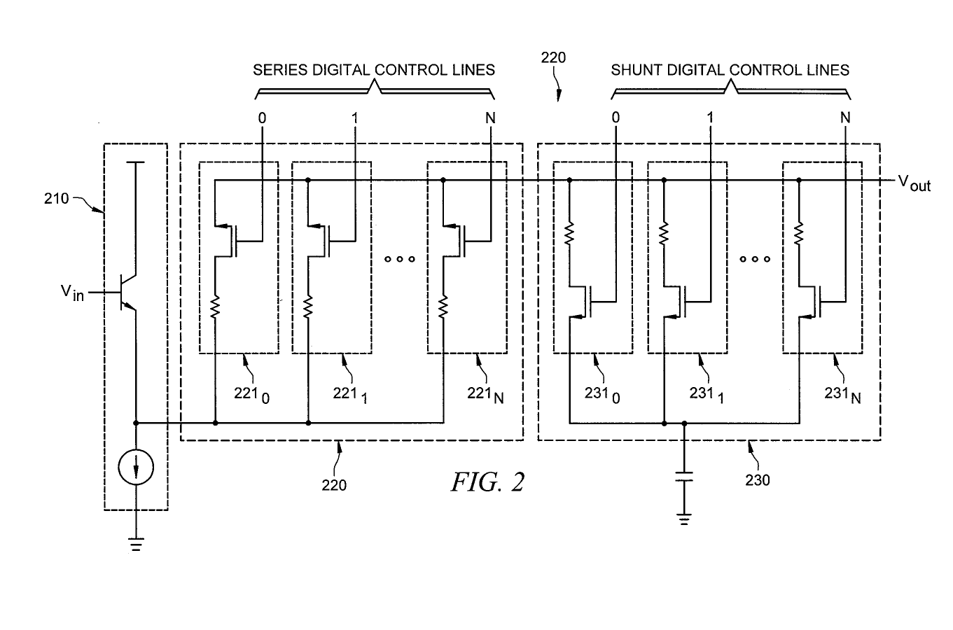

FIG. 2 is an illustration of exemplary system 200 adapted according to one embodiment of the invention. In fact, system 200 conforms to the specifications of system 100 (FIG. 1) and may be used for AGC. System 200 includes input component 210, first adjustable impedance component 220, and second adjustable impedance component 230. Typically, many embodiments will use Vₒᵤₜ as an input to an amplifier (not shown) or other active circuit element.

Input component 210 in this example is an emitter follower, which is used to provide a buffer between the attenuator circuit (components 220 and 230) and circuitry on the other side of input component 210. Emitter followers, such as shown in system 200, may be adaptable to a number of embodiments because they generally cause minimal distortion, while providing separation between the source impedance and the input impedance of the attenuator circuit. Input component 210 is not limited to an emitter follower in various embodiments. For instance, input component 210 may simply be a wire contact receiving Vᵢₙ or may be a source-follower arrangement, or the like.

The attenuator circuit of the embodiment of FIG. 2 is a resistor divider including series component 220 and shunt component 230. Each adjustable impedance component 220 and 230 includes a plurality of legs (221 and 231, respectively) that conduct current when “turned on” by a switch, such as a Field Effect Transistor (FET), Bipolar Junction Transistor (BJT), or other type of switch. The number of “on” legs and their respective individual impedances determine the impedance of each component 220 and 230 at a given time. Thus, by selectively turning legs on or off through digital control lines, the impedances of the components, and, therefore, the attenuation of the circuit, can be controlled. The digital control lines may be connected in some embodiments to control logic, such as a feedback loop that measures signal level, distortion, and/or noise and adjusts the attenuator circuit accordingly. It should be noted, however, that in some embodiments not all legs are switchable. For example, each component 220 and 230 may include one leg 221, 231 that is not switchable so that the current paths are closed even when no legs are switched on, thereby providing maximum impedance and preventing an open circuit. For simplification, the impedance of component 220 is referred to as Zₛₑᵣ, and the impedance of component 230 is referred to as Zₛₕ.

Typically, the impedance (Zᵢₙ) as seen by input component 210 is approximately equal to Zₛₕ in parallel with the input impedance of the following stage (Z_{L}) plus Zₛₑᵣ. The impedance (Zₒᵤₜ) seen by a component at Vₒᵤₜ is approximately equal to Zₛₕ in parallel with the sum of Zₛₕ and the output impedance of the previous stage (Z_{S}). Also, the attenuation is approximately equal to the sum of Zₛₕ and Zₛₑᵣ divided by Zₛₕ. These relations are given in equations 1, 2, and 3, wherein “approximately” is plus or minus 20 percent:

$$\begin{matrix}{Z}_{in} \approx {Z}_{ser} + {Z}_{sh} // {Z}_{L} & ( 1 ) \\ {Z}_{out} \approx {Z}_{sh} // ( {Z}_{ser} + {Z}_{s} ) & ( 2 ) \\ Attenuation \approx \frac{{Z}_{sh} + {Z}_{ser}}{{Z}_{sh}} & ( 3 )\end{matrix}$$

In some embodiments, it is advantageous to maintain a carrier-to-noise ratio at the output of an active element following a given attenuator approximately constant or increasing throughout the range of attenuation. The noise of interest including noise from components 220 and 230 and any active element at Vₒᵤₜ such as, for example, an amplifier (not shown). Additionally, in some embodiments it is desirable to maintain a carrier-to-distortion ratio at the output of an active element following a given attenuator approximately constant or increasing throughout the range of attenuation. The distortion of interest including distortion from components 220 and 230 and any active element at Vₒᵤₜ such as, for example, an amplifier (not shown).

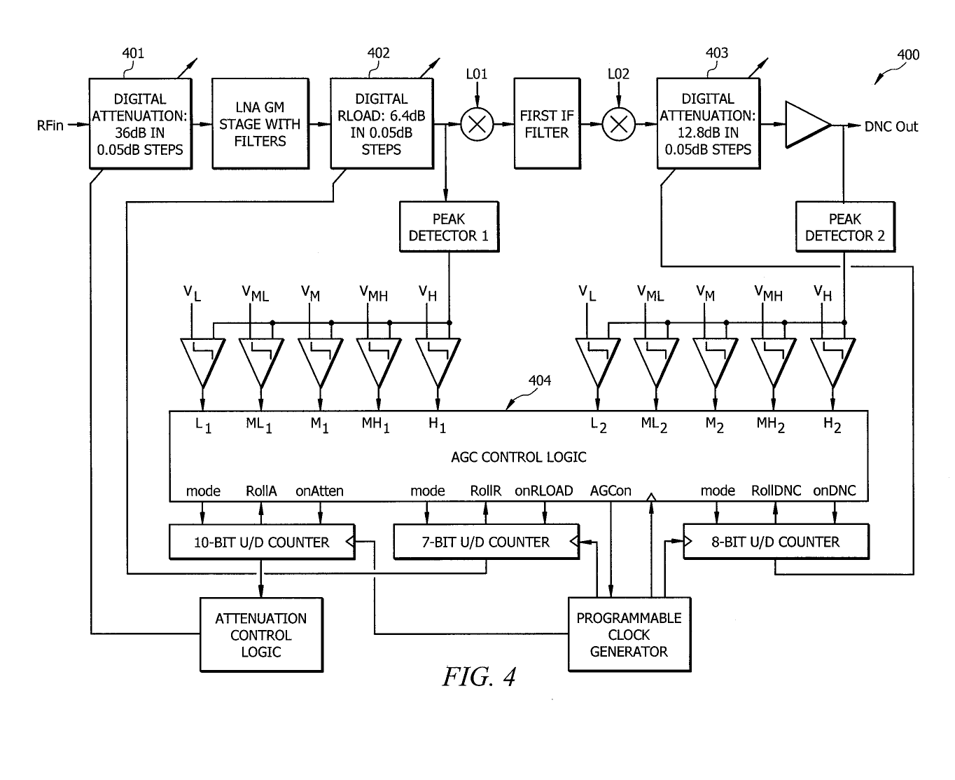

In general, Zᵢₙ is maintained relatively high in some embodiments in order to minimize distortion from the emitter follower in component 210. Also, many embodiments maintain Zₒᵤₜ relatively low in order to keep noise from the amplifier at Vₒᵤₜ low. Maintaining the relationships of Zᵢₙ and Zₒᵤₜ may help to provide an attenuator circuit that performs similarly to the examples in FIGS. 3 and 4. The values of Zᵢₙ and Zₒᵤₜ may also be determined, at least in part, by impedance matching concerns with regard to adjacent circuit elements.

The high value for Zᵢₙ and the low value for Zₒᵤₜ depend on the specific application for which the attenuator is designed. For example, distortion caused by an emitter follower usually depends, at least in part, on the current therethrough and on the impedance immediately following it—in this case, Zᵢₙ. Also, an amplifier will usually experience better noise reduction if its source impedance seen by its input—in this case, the output impedance of the attenuator circuit, is lower than or equal to the optimal source impedance of the amplifier. Typically, an optimal source impedance of an amplifier is specific to each amplifier and represents the impedance wherein input referred voltage noise is equal to input referred current noise multiplied by source impedance. In one specific example, a system has an amplifier input at Vₒᵤₜ, approximately 10 mA of current from the emitter follower of component 210, a floor value for Zᵢₙ of 100 Ohms, and a ceiling value for Zₒᵤₜ of 75 Ohms.

Any given attenuation level may be achieved by a multitude of (Zₛₑᵣ, Zₛₕ) value pairs. Appropriate (Zₛₑᵣ, Zₛₕ) value pairs may be determined using the constraints provided by a ceiling value for Zₒᵤₜ, a floor value for Zᵢₙ, equations 1, 2, and 3, and the carrier-to-noise and carrier-to-distortion relationships (described above) to advantageously provide attenuation in many applications. Specifically, in one example, a control system determines a desired attenuation level and adjusts the values of impedance components 220 and 230 to provide that attenuation level while staying within the constraints.

One advantage of some embodiments of the present invention is that the attenuator circuit can be disposed in a single semiconductor chip, thereby facilitating the production of larger single-chip or all-semiconductor systems. In fact, various embodiments may be included in chip-based RF tuners.

Returning to FIG. 2, in many embodiments, the switches in legs 221 and/or 231 of components 220 and 230 cause some amount of distortion. For example, when Metal Oxide Semiconductor (MOS) FETs are used as switches in legs 221 and/or 231, distortion caused thereby can often be a design or operation concern. This phenomenon is more likely when Zₛₑᵣ is high and the voltage drop is high across a particular switch in one or more legs 221. In system 200, each leg 221 and 231 includes a MOSFET switch and a resistor in series therewith. The ratio of resistance from the resistor and resistance from the MOSFET can be tailored for specific legs. Thus, when Zₛₑᵣ is high, the leg or legs 221 used in component 220 can have a resistance ratio of, e.g., 80% resistor and 20% MOSFET. As more legs 221 are switched on to lower the impedance of component 220, the resistance ratios of additional legs 221 may decrease to e.g., 50% resistor and 50% MOSFET, even as low as 100% MOSFET in a few legs 221. Such a design may help to reduce distortion, especially in component 220. Oftentimes, the voltage drop across component 230 will not have an appreciable affect on distortion, so resistance ratios of, e.g., 80% resistor and 20% MOSFET, can be appropriate for many, if not all, of legs 231.

The number of legs in a given embodiment can often determine the sizes of the incremental changes in attenuation that are available from the circuit. In one example, fourteen legs 221 in component 220 and eight legs 231 in component 230 are used to provide attenuation in 0.05 dB steps over a 36 dB range. In this example, legs 221 of component 220 provide coarse adjustments in the attenuation level, while legs 231 of component 230 provide fine tuning. At minimum attenuation (Zₛₑᵣ high, Zₛₕ low), the first few legs 221 of component 220 switch out between 0.5 db and 1 dB attenuation increases, with legs 231 of component 230 providing fine tuning in a binary-coded manner. As attenuation increases, each leg 221 of component 220 represents a step of up to 3 dB, such that the frequency of switching in legs 221 of component 230 increases.

FIG. 3 is an illustration of exemplary method 300 adapted according to one embodiment for providing AGC in a circuit, such as system 100 (FIG. 1) or system 200 (FIG. 2). Method 300 maybe performed, for example, by a control system implemented in hardware and/or software that keeps signal levels within an acceptable range in a circuit. In step 301, a voltage input signal is received. In step 302, the level (e.g., power value) of the signal is measured. In one example, the signal level may be measured at one or more places, including at Vₒᵤₜ or further downstream, such as at the output of an amplifier that uses Vₒᵤₜ for its input.

At step 303, it is determined from the measurement of step 302 if the signal level is above a desired level. If the signal level is above the desired level, then attenuation is increased in step 304 in order to keep the signal level close to the desired level, which in some embodiments means keeping the signal level approximately constant. Increasing the attenuation can be performed in one example by increasing Zₛₑᵣ of component 220 (FIG. 2) relative to Zₛₕ of component 230. Further, the increase in attenuation in step 304 is performed so that a carrier-to-noise ratio at the output of an active element following a given attenuator is approximately constant or increasing throughout the range of attenuation. Additionally, a carrier-to-distortion ratio at the output of an active element following a given attenuator is kept approximately constant or increasing throughout the range of attenuation. Thus, distortion and noise levels are measured and accounted for when increasing attenuation.

In step 305, it is determined if the signal level is below a desired level. If the signal level is below the desired level, then the attenuation is decreased in step 306. Decreasing attenuation can be performed in one example, by decreasing Zₛₑᵣ of component 220 (FIG. 2) relative to Zₛₕ of component 230. Further, the decrease in attenuation is performed such that a carrier-to-noise ratio at the output of an active element following a given attenuator is approximately constant or increasing throughout the range of attenuation. Additionally, a carrier-to-distortion ratio at the output of an active element following a given attenuator is kept approximately constant or increasing throughout the range of attenuation. Thus, similar to step 304, distortion and noise levels are measured and accounted for when decreasing attenuation.

In one or more embodiments, measuring, increasing, and/or decreasing are performed continuously or frequently to keep a signal level constant over a period of time or indefinitely. It should be noted that method 300 is for example only, and various embodiments are not limited to any one method of operation. For instance, although the method 300 is depicted as a series of sequential steps in FIG. 3, it is within the scope of embodiments to differ therefrom. Thus, step 301 may be performed continuously throughout method 300 rather than once, as shown, and, further, it may be performed simultaneously with other steps. Also, steps 303 and 305 may be performed as a single step that measures signal level or change in signal level and performs steps 304 and 306 accordingly.

Designers have been reluctant in prior art systems to create or use digital attenuators because the discrete steps may often cause a control system not to settle since there is usually some amount of error between the closest available step and the ideal value. Accordingly, a control system that performs method 300 may also include operations that allow it to settle at one or more discrete value as it operates continuously or frequently, such as, for example, by tolerating some amount of error.

FIG. 4 is an illustration of exemplary system 400 adapted according to one embodiment of the invention. System 400 is a gain control loop that includes three gain control blocks 401-403. Each gain control block 401-403 is an attenuator circuit as shown in FIG. 1. System 400 uses gain control blocks 401-403 for small gain steps throughout a RF receive signal path both to control an overall signal level in the RF signal path and to control signal levels at discrete points in the RF signal path.

System 400 uses AGC control logic 404 to measure signal levels and to control gain control blocks 401-403, as described in FIG. 3. An example operation of AGC control logic 404 is to determine an appropriate attenuation level of each one of gain control blocks 401-403. AGC control logic 404 adjusts the values of individual impedance elements in each one of gain control blocks 401-403 by selecting specific, discrete elements to achieve the desired attenuation level, each of the discrete elements having some amount of impedance. In this example, the values of the individual impedance elements in each one of gain control blocks 401-403 is determined, additionally, in view of constraints—a ceiling value for Zₒᵤₜ, a floor value for Zᵢₙ, equations 1, 2, and 3, and the carrier-to-noise and carrier-to-distortion relationships (described above). The values of the individual impedance elements may be determined by software or logic inside AGC control logic 404.

While the embodiments described above show two adjustable impedance components, various embodiments are not limited thereto. For instance, an example configuration includes one fixed impedance component and one adjustable impedance component. Another example embodiment includes three or more adjustable impedance components. In fact, arrangements with any number of adjustable impedance components are within the scope of the invention.

Further, there is no requirement that configurations must conform to the voltage-divider design of FIGS. 1 and 2. For instance, an R-2R ladder or other such arrangement may be used in some embodiments.

Also, while the examples in FIG. 2 shows the discrete legs as including resistors, various embodiments are not so limited. In addition to or alternatively to discrete, resistive elements, some embodiments may use reactive elements, such as capacitors and/or inductors to provide selectable impedance. In fact, reactive impedance from capacitors may be especially useful when attenuating lower frequency signals.

Various embodiments of the present invention may provide one or more advantages over prior art AGC systems. For example, some embodiments can be readily adapted for use in a semiconductor chip, thereby simplifying a tuner design and saving space compared to systems that use off-chip attenuators. Further, according to some embodiments, one or more attenuator circuits can be placed in an RF signal path, including immediately before the first amplifier in the signal path, thereby eliminating the need for AGC inside a distortion-causing amplifier. Still further, according to some embodiments, the number of selectable, discrete elements in a given adjustable impedance component is scalable and can provide nearly any desired step resolution for a given application.

Some prior art systems use a particular method of selecting the discrete legs. In one example prior art system, the shunt attenuator circuit is a binary array (e.g., where the discrete legs are R, 2R, 4R, etc.) and the series attenuator circuit is a “thermometer” array (e.g., where the discrete legs are R′, 2R′, 3R′, etc.). For each step in the series circuit, the entire array of legs in the shunt circuit is stepped through. For instance, as one leg in the series circuit is switched, the shunt circuit is reset to a particular state, such as by use of a binary code 000 or 001. Then, the various values of the binary code for the shunt circuit are stepped through before the shunt circuit is reset again and the next step is made at the series circuit.

However, with each step at the series circuit, there is also a step made at the shunt circuit as the shunt circuit resets. In other words, in most steps only one leg is switched at a time, but at steps of the series circuit, legs in both the shunt and series circuits are switched. If the attenuator circuit has capacitance at its output (e.g., a parasitic capacitance) in parallel with the shunt circuit, and if the RF signal is at a high enough frequency, the output impedance of the attenuator circuit may swing drastically (e.g., 10% or more) when legs in the shunt and series circuits are switched at the same time. In the context of a television tuner that uses such an attenuator circuit, drastic swings in the output impedance can cause large signal amplitude steps, leading to brief periods of malfunction so that the user sees macroblocking or other video artifacts on the screen.

Various embodiments of the invention provide techniques for operation of an attenuator circuit that can be used instead of, or in addition to, prior art techniques. For instance, various embodiment switch only the series circuit or only the shunt circuit at a given time so that output impedance varies only gradually at each step. Various embodiments may also provide smaller changes in attenuation at each step than do some prior art techniques.

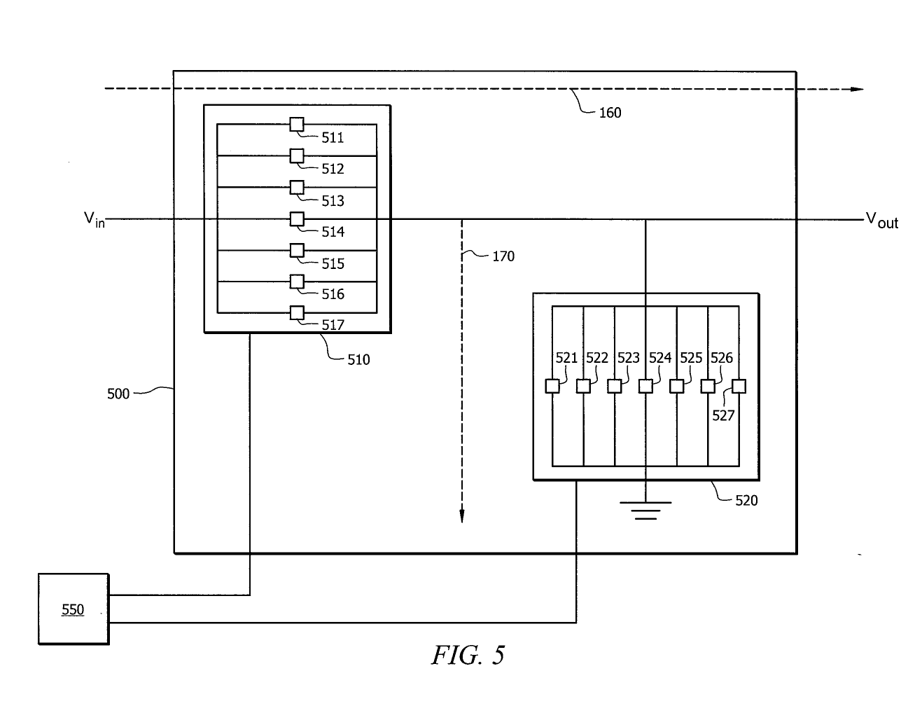

FIG. 5 is an illustration of exemplary attenuator circuit 500, adapted according to one embodiment of the invention. Attenuator circuit 500 can be used as one of the gain control blocks 401-403 of FIG. 4 and can also be used in other RF systems with gain control, as well. In fact, attenuator circuit 500 can be adapted for use in any RF application that uses attenuation blocks, such RF applications including dual conversion tuners, direct conversion tuners, RF systems with AGC, externally controlled systems with gain control, and the like.

Attenuator circuit 500 includes impedance components 510 and 520, where component 510 is a series impedance control component, and component 520 is a shunt impedance control component. Impedance component 510 includes discrete, selectable legs 511-516. For purposes of illustration, leg 517 is always on so that the circuit is closed even when all of legs 511-516 are off. However, the control of the series component 510 and the shunt component 520 can be designed such that at least one of the legs is always on, but it may not be the same leg. Selectable legs 511-516 form a binary array. For instance, leg 511 may have an impedance value of R, leg 512 may have a value of 2R, leg 513 may have a value of 4R, leg 514 may have a value of 8R, leg 515 may have a value of 16R, and leg 516 may have a value of 32R.

Similarly, impedance component 520 includes selectable legs 521-526, where leg 527 is always on. Legs 521-526 are also in a binary array where leg 521 has an impedance value of R′, leg 522 has a value of 2R′, leg 523 has a value of 4R′, leg 524 has a value of 8R′, leg 525 has a value of 16R′, and leg 526 has a value of 32R′.

Each of legs 511-516 and 521-526 are selectable using digital signals from control circuit 550. Control circuit 550 may be on the same chip as attenuator circuit 500 or may be external thereto. Control circuit 550 may operate in a manner similar to that of AGC control 404 of FIG. 4, where a signal level is measured and attenuator circuits are adjusted in response thereto. Furthermore, each component 510, 520 is shown with six selectable legs, though various embodiments may be scaled as desired so that more or fewer legs may be used in a given application.

Attenuator circuit 500 is a resistor divider. Thus, at maximum gain, legs 511-516 are on, and legs 521-526 are off. In the following example, attenuator circuit 500 begins with legs 511-516 on. Table 1 shows the attenuation codes that are stepped through in series component 510, where each attenuation code is decoded into a 3-bit binary codeword (b₀, b₁, b₂). In the binary codeword, a 1 indicates that a leg is on and a 0 indicates that a leg is off. Table 2 shows how b₀, b₁, b₂ switch from 000 to 111.

TABLE 1

| | R | 2R | 4R | 8R | 16R | 32R |
|---|---|---|---|---|---|---|
| 0-7 | b₂ | b₁ | b₀ | 1 | 1 | 1 |
| 8-15 | 0 | b₂ | b₁ | b₀ | 1 | 1 |
| 16-23 | 0 | 0 | b₂ | b₁ | b₀ | 1 |
| 24-32 | 0 | 0 | 0 | b₂ | b₁ | b₀ |

TABLE 2

| b₂ | b₁ | b₀ |
|---|---|---|
| 0 | 0 | 0 |
| 0 | 0 | 1 |
| 0 | 1 | 0 |
| 0 | 1 | 1 |
| 1 | 0 | 0 |
| 1 | 0 | 1 |
| 1 | 1 | 0 |
| 1 | 1 | 1 |

At attenuation codes zero to seven, a binary number 111 is applied to legs 511-513, and at each step of series component 510 the binary number counts down until it eventually reaches 000. After attenuation codes 0-7 are exhausted, attenuation codes 8-15 are applied. When using attenuation codes 8-15, leg 511 is always off, and the binary number 111 is applied to legs 512-514. Legs 515, 516 are on, and the binary number counts down until it reaches 000. Table 1 shows that the binary numbers 111-000 are shifted over to the next most significant leg at each eighth attenuation code. It should be noted that the binary code words have a smaller number of bits than the number of legs 511-516.

Operation of shunt component 520 is similar to that described immediately above. Table 3 shows the attenuation codes that are stepped through in shunt component 520. At attenuation codes zero to seven, a binary number 000 is applied to legs 521-523, and at each step of shunt component 510 the binary number counts up until it eventually reaches 111. After attenuation codes 0-7 are exhausted, attenuation codes 8-15 are applied. When using attenuation codes 8-15, leg 521 is always on, and the binary number 000 is applied to legs 522-524. Legs 525, 526 are off, and the binary number counts up until it reaches 111. Table 3 shows that the binary numbers 000-111 are shifted over to the next least significant leg at each eighth codeword. Once again, the binary code words have a smaller number of bits than the number of legs 521-526.

TABLE 3

| | 32R′ | 16R′ | 8R′ | 8R′ | 2R′ | R′ |
|---|---|---|---|---|---|---|
| 0-7 | b₀ | b₁ | b₂ | 0 | 0 | 0 |
| 8-15 | 1 | b₀ | b₁ | b₂ | 0 | 0 |
| 16-23 | 1 | 1 | b₀ | b₁ | b₂ | 0 |
| 24-32 | 1 | 1 | 1 | b₀ | b₁ | b₂ |

In an exemplary embodiment, the attenuation steps from high gain to low gain are made in the following manner. Attenuation codes are used in an alternating pattern between series component 510 and shunt component 520. The alternating pattern is not limited to alternating only at single steps. For instance, in one example, two or more steps are taken by shunt component 520 for each step that is taken by series component 510. In another example, two or more steps are taken by series component 510 for each step that is taken by shunt component 520.

In this example, only one leg of the components 510 at a time is switched. Thus, each attenuation step change is the result of a single leg being switched. Moreover, in some embodiments, each step is the result of only a single leg being switched at a time, where a single leg being switched can refer to one leg being switched on as another leg is switched off.

The alternating pattern is used until the impedance of shunt component 520 reaches a pre-determined value. The pre-determined value can be different for each application. In many embodiments, the pre-determined value depends on frequency-independent ground impedance in the circuit. In such embodiments, the pre-determined value is chosen to be high enough so that the output impedance of attenuator circuit 500 is not dominated by, e.g., bond wire inductance at the ground, which is heavily dependent on frequency of the RF signal.

After the pre-determined impedance value of shunt component 520 is reached, attenuator circuit 500 changes to another pattern. In the second pattern, only the legs of series component 510 are switched.

During operation, attenuator circuit 500 may or may not step through the entire range of gain. In some instances, attenuator circuit 500 may stay within the first pattern, where attenuation steps are alternatingly carried out by switching legs in series and shunt components 510, 520. In other instances, attenuator circuit 500 may stay within the second pattern, where attenuation steps are carried out using only series component 510. In any event, the full range of attenuation is available.

Furthermore, the example above describes a scenario wherein gain decreases (i.e., attenuation increases), though the scope of embodiments is not so limited. In other embodiments, gain may start low and then increase over a range. In such a scenario, attenuator circuit 500 may step through the attenuation codes in a reverse order from the order described above. Also, in an increasing gain scenario, attenuator circuit 500 may perform the second pattern first and the first pattern subsequently to the second pattern.

An important feature of the above-described technique is that the output impedance of attenuator circuit 500 can be changed quite gradually. The output impedance is influenced by the impedance of shunt component 520 and any ground inductance more than it is influenced by the impedance of series component 510. Therefore, output impedance can be stabilized somewhat by leaving the impedance of shunt component 520 at the predetermined level, as described above. Also, since each impedance step is characterized by a single component 510, 520 being switched, large output impedance changes due to both components 510, 520 being switched can be avoided.

In many embodiments, the magnitude of change in output impedance for each attenuation step can be kept low enough to ensure better performance from the RF device. As noted above, a relatively high output capacitance and a relatively high frequency of an RF signal, when combined with a large and instantaneous change in output impedance, can often result in performance degradation for an RF device. Each device is different, and each device can be expected to have a different tolerance for instantaneous output impedance changes. The technique described above can be adapted for use in various RF devices by providing an appropriate number of legs and a process of switching those legs that keeps instantaneous changes in output impedance within a range of tolerance of a device. For instance, many High Definition (HD) television tuners would be able to operate well when output impedance varies within one percent for each attenuation step. In another example, many RF devices would operate well if output impedance varies within five or ten percent with each attenuation step. However, the scope of embodiments is not limited to any particular range.

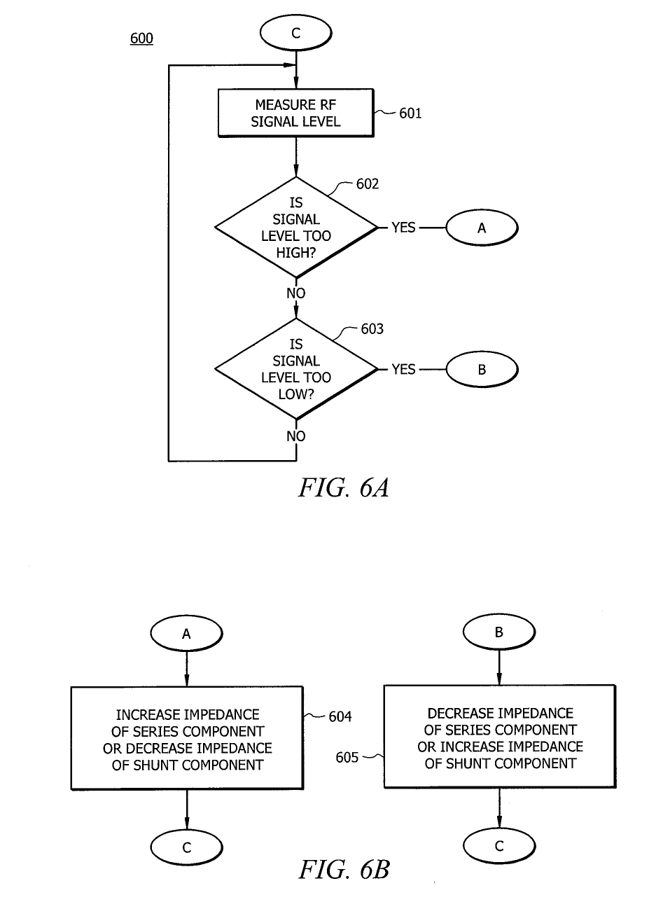

FIGS. 6A and 6B are an illustration of exemplary method 600 adapted according to one embodiment of the invention. Method 600 may be performed in some embodiments by an AGC controller to adjust gain in an RF signal path. In another embodiment, method 600 is performed by an external gain control system. Method 600 is not limited to any particular implementation.

In block 601, the RF signal level is measured. In blocks 602 and 603 it is discerned whether the signal level is too low or too high, where too low and too high may be determined, e.g., by pre-set thresholds, discerning an effect of the signal level on device operation, and/or the like. If the signal level is too high, then in block 604 total attenuation is increased. In the example of a resistor divider configuration, such as is shown in FIG. 5, impedance of the series component is increased or impedance of the shunt component is decreased. Whether attenuation is increased or decreased, in this embodiment only one of the components is switched at a time through most or all of the range of gain. Also, in some embodiments, many of the gain steps include switching only one leg at a time.

If the signal level is too low, attenuation is decreased. In the example of FIG. 5, the impedance of the series component is decreased or the impedance of the shunt component is increased. The signal level is periodically or continually monitored to ensure that the signal level is within an acceptable range.

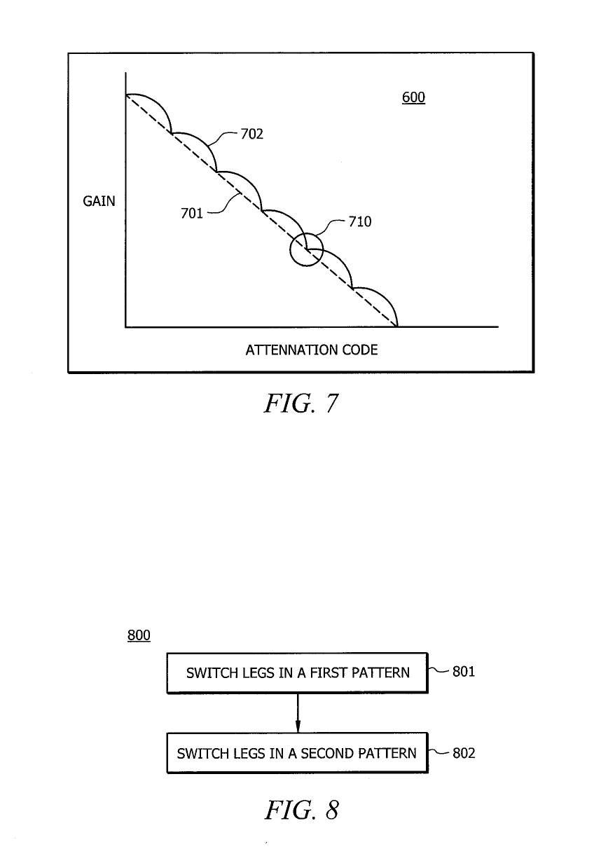

FIG. 7 shows graph 700, which plots gain (in dB) against attenuation codes in an example embodiment. An ideal scenario is shown in curve 701, where gain is more or less linear over a wide range of attenuation codes. Some techniques described above approximate curve 701 as shown in curve 702 by taking gradual attenuation steps with binary arrays. Point 710 is an example point where the binary control word is shifted over to the next most significant leg in the series component of FIG. 5. Shifting the binary control words, in this example, provides a scalloped curve that is acceptable in many implementations.

FIG. 8 is an illustration of exemplary method 800 adapted according to one embodiment of the invention. Method 800 is a specific example of a technique to use in performing method 600, and it may help in some embodiments to provide an acceptable gain curve as well as an acceptable change in output impedance. In block 801, the legs are switched in a first pattern, and in block 802, the legs are switched in a second pattern. In one example, the first pattern includes switching selectable impedance legs alternatingly between the series and the shunt components. In another example, the second pattern includes switching legs only in the series component. In yet another example, the second pattern includes switching legs only in the shunt component. Moreover, in some instances, an alternating pattern may be applied after a series-only or shunt-only pattern is applied.

The description above provides techniques for gain control in an RF device. However, the scope of embodiments is not limited to those explicitly described above. For instance, an attenuator circuit may be operated according to the methods of FIGS. 6 and 8 in a portion of the dynamic range and may be operated according to other methods in another portion of the dynamic range.

Various embodiments provide one or more advantages over prior art techniques. For instance, embodiments that control the change in output impedance may provide more reliable operation through elimination or reduction of drastic changes in output impedance. Also various embodiments are especially adaptable to broadband applications that have a frequency range of four and a half octaves or more. Specifically, higher frequencies in the RF signal may cause noticeable impedance at the ground when there is inductance present. However, various embodiments may adjust the impedance of the series and/or shunt component to keep the output impedance from being dominated by the impedance arising from the inductance. A more stable output impedance can often provide more reliable operation, even when there is capacitance at the output of the attenuator circuit. Still further, various embodiments provide a substantially linear gain slope (in dB) over a relatively large dynamic range (e.g., 6 dB or more), using various techniques, such as the techniques described above with respect to FIGS. 6 and 8.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for controlling an attenuator circuit, where the attenuator circuit includes a shunt attenuation component with a first plurality of selectable legs and a series attenuation component with a second plurality of selectable legs, the attenuator circuit providing digitally-selectable impedance values in discrete steps, said method comprising:
stepping through a first plurality of attenuation codes in said series component; and
stepping through a second plurality of attenuation codes in said shunt component, wherein attenuation is adjusted with said first and second plurality of attenuation codes by switching only one of said shunt attenuator component and series attenuator component at each attenuation step.

2. The method of claim 1 in which only one of said selectable legs is switched at each attenuation step.

3. The circuit of claim 1 in which each of said selectable legs is selectable by an associated, respective transistor, each said selectable leg having an associated impedance.

4. The method of claim 1 in which the first and second pluralities of selectable legs comprise binary weighted impedance arrays.

5. The method of claim 1 in which stepping through the first and second plurality of attenuation codes includes:
alternating between adjusting the series component and adjusting the shunt component until the shunt component reaches a predetermined attenuation level; and
after the shunt component reaches the pre-determined attenuation level, stepping through a portion of dynamic range using only the series component.

6. The method of claim 1 in which each attenuation step is accompanied by a change in output impedance of less than five percent.

7. The method of claim 1 in which each of said attenuation codes of the first plurality of attenuation codes corresponds to a respective binary word, the respective binary words having fewer bits than a number of selectable legs in the second plurality of selectable legs.

8. The method of claim 7 in which stepping through the first plurality of attenuation codes comprises:
applying said respective binary words to a first portion of the second plurality of selectable legs and then shifting to a second portion of the second plurality of selectable legs, the second portion including a more significant set of selectable legs than in the first portion.

9. The method of claim 1 wherein each of said attenuation codes of the second plurality of attenuation codes corresponds to a respective binary word, the respective binary words having fewer bits than a number of selectable legs in the first plurality of selectable legs.

10. A system for controlling an attenuator circuit, where the attenuator circuit includes a shunt attenuation component with a first plurality of selectable legs and a series attenuation component with a second plurality of selectable legs, the attenuator circuit providing digitally-selectable impedance values in discrete steps, said system comprising:
means for adjusting attenuation in discrete steps by applying a first pattern that alternates between switching at least one leg of said first plurality of selectable legs and switching at least one leg of said second plurality of selectable legs;
means for applying said first pattern until one of said shunt component and said series component reaches a predetermined level of impedance; and
means for adjusting attenuation over a range of gain in a plurality of discrete steps by applying a second pattern that switches selectable legs only in one of said shunt component and said series component.

11. The system of claim 10 in which the second pattern switches selectable legs in the series component.

12. The system of claim 10 in which the second pattern switches selectable legs in the shunt component.

13. The system of claim 10 in which the first and second pluralities of selectable legs comprise respective binary weighted impedance arrays.

14. The system of claim 10 wherein each of said selectable legs is selectable by an associated, respective transistor, each said selectable leg having an associated impedance.

15. The system of claim 10 further including:
digital control logic operable to measure a power level of a Radio Frequency (RF) signal and to provide digital signals to said attenuator circuit to achieve an attenuation of said RF signal based at least in part on said measured power level.

16. The system of claim 10 in which said attenuator circuit is arranged as a voltage divider.

17. A system for controlling an attenuator circuit, where the attenuator circuit includes a shunt attenuation component with a first plurality of selectable legs and a series attenuation component with a second plurality of selectable legs, the attenuator circuit providing digitally-selectable impedance values in discrete steps, said system comprising:
a control system that uses digital signals to select ones of the first and second plurality of selectable legs, the control system performing the following actions:
stepping through a dynamic range using a plurality of attenuation steps, wherein only one of said shunt attenuation component and said series attenuation component is switched at a given attenuation step, and wherein each attenuation step experiences no more than a five percent change in output impedance of the attenuator circuit.

18. The system of claim 17 in which only one of said selectable legs is switched at each attenuation step.

19. The system of claim 17 in which the first and second pluralities of selectable legs comprise respective binary weighted impedance arrays.

20. The circuit of claim 17 in which the digital control logic measures a power level of a Radio Frequency (RF) signal and provides said digital signals to the attenuator circuit to achieve an attenuation of said RF signal based at least in part on said measured power level.

21. The system of claim 17 wherein said attenuator circuit is arranged as a voltage divider.

22. The system of claim 17 in which stepping through the dynamic range comprises:
alternating between adjusting the series component and adjusting the shunt component until the shunt component reaches a predetermined attenuation level; and
after the shunt component reaches the pre-determined attenuation level, stepping through a portion of dynamic range using only the series component.
